(19) United States
(12) Patent Application Publication
(10) Pub. No.: US 2017/0098478 A1
(43) Pub. Date: Apr. 6, 2017

(54) METHOD AND APPARATUS FOR IMPROVING YIELD FOR NON-VOLATILE MEMORY

(71) Applicant: Macronix International Co., Ltd., Hsin-Chu (TW)

(72) Inventors: Chih-Wei Lee, New Taipei City (TW); Cheng-Hsien Cheng, Yunlin County (TW); Shaw-Hung Ku, Hsinchu City (TW); Wen-Pin Lu, Hsinchu County (TW)

(21) Appl. No.: 14/873,486

(22) Filed: Oct. 2, 2015

(51) Int. Cl. G11C 29/38; G11C 16/26; G11C 29/44; G11C 16/14

(52) U.S. Cl. CPC G11C 29/38; G11C 16/14; G11C 16/26; G11C 29/44

(57) ABSTRACT

A method, apparatus and computer program product are provided in order to test word line failure of a non-volatile memory device. An example of the method includes performing a failure screening of the non-volatile memory device, wherein the non-volatile memory device comprises one or more word lines; identifying a point of failure located between a first word line and a second word line; and marking the first word line and the second word line as a single word line in response to identifying the point of failure between the first word line and the second word line.

### TECHNOLOGICAL FIELD

Embodiments of the present invention relate generally to semiconductor devices and, in particular, methods for testing word line failure and yield of semiconductor memory devices.

### BACKGROUND

Memory devices are typically classified as either volatile semiconductor devices, which require power to maintain storage of data, or non-volatile semiconductor devices, which can retain data even upon removal of a power source. An example non-volatile memory device is a flash memory device, which generally may be classified as NOR or NAND flash memory devices. Such flash memory devices may stack cells, or layers, on top of each other taking the form of a three-dimensional (3D) NAND architecture. When faster program and erase speeds are desired, 3D NAND flash memory is typically utilized, in large part, due to its serialized structure whereby program and erase operations may be performed on entire strings of memory cells. Due to the scalability of the 3D NAND, cell uniformity, word line and bit line characteristics are critical in overall performance the flash memory devices.

Conventional NAND architecture failure modes are often caused by defects during the semiconductor manufacturing process, such as open circuits and short circuits on bit or word lines. Testing and managing of both bit line and word line breakdowns are critical for the scalability and yield of the 3D NAND. Due to the nature of the NAND architecture, each bit line is independent and can be tested separately. Bit line failures are usually handled by error correction code (ECC) or by added redundancy. Word line failures are usually addressed by marking blocks with word line failures as “bad,” such that these blocks are unused. However, marking an entire block as bad in response to a word line failure may disable a relatively large component of the NAND device due to the series connection between the memory cells along the word line. Especially in the case of 3D NAND structure, the size of a bad block may represent an even larger proportion of the overall device due to the multiple stacked layers of cells. As such, marking an entire block as bad due to a single word line failure may not be economical, as such techniques may have a dramatic impact on the yield of usable memory devices from a given manufacturing process.

### BRIEF SUMMARY OF EXEMPLARY EMBODIMENTS

Methods, apparatuses and computer program products are therefore provided according to example embodiments of the present invention in order to test word line failure of a non-volatile memory device. Embodiments include a method for testing word line failure of a non-volatile memory device. The method includes performing a failure screening of the non-volatile memory device, wherein the non-volatile memory device comprises one or more word lines, identifying a point of failure located between a first word line and a second word line.

The method may also include applying a bias voltage to both of the first word line and the second word line respectively in an instance in which a function is performed on the non-volatile memory device. The function may be one of program, erase, or read. The method may also include identifying a plurality of points of failure, identifying a block associated with a portion of the plurality of points of failure, wherein the block is a region of the non-volatile memory device, determining a total number of points of failure within the block, and marking the block as a bad block in an instance in which the total number of points of failure exceeds of a predetermined threshold value. The point of failure may be a shortage between the first word line and the second word line. The non-volatile memory device may be one of a flash memory device, 3D NOR memory device, 3D ROM memory device, 2D NAND memory device, 3D NAND memory device, 2D NOR memory device, MOS device having cells under regular arrangement, or a device configured for voltage application under regular arrangement.

Embodiments also include an apparatus for testing word line failure of a non-volatile memory device. The apparatus includes testing circuitry and modification circuitry. The testing circuitry is configured to perform a failure screening for a non-volatile memory device, wherein the non-volatile memory device comprising one or more word lines, and identify a point of failure located between a first word line and a second word line. The modification circuitry is configured to mark the first word line and the second word line as a single word line in response to identifying the point of failure between the first word line and the second word line.

The modification circuitry may be further configured to apply a bias voltage to both of the first word line and the second word line respectively in an instance in which a function is performed on the non-volatile memory device. The function may be one of program, erase, or read. The modification circuitry may be further configured to mark the first word line and the second word line as a common word line. The apparatus may be further configured to identify a plurality of points of failure, identify a block associated with a portion of the plurality of points of failure, wherein the block is a region of the non-volatile memory device, determine a total number of points of failure within the block, and mark the block as a bad block in an instance in which the total number of points of failure exceeds of a predetermined threshold value. The point of failure may be a shortage between the first word line and the second word line. The predetermined threshold value may be five. The non-volatile memory device may be one of a flash memory device, 3D NOR memory device, 3D ROM memory device, 2D NAND memory device, 3D NAND memory device, 2D NOR memory device, MOS device having cells under regular arrangement, or a device configured for voltage application under regular arrangement.

Embodiments may also include a non-transitory computer readable storage medium comprising instructions that, when executed by a processor, configures a processor. The processor is configured to perform a failure screening of the non-volatile memory device, wherein the non-volatile memory device comprising one or more word lines, identify a point of failure located between a first word line and a second word line, and mark the first word line and the second word line as a single word line in response to identifying the point of failure between the first word line and the second word line.

The instructions may also configure the processor to apply a bias voltage to both of the first word line and the second word line respectively in an instance in which a function is performed on the non-volatile memory device. The function may be one of program, erase, or read. The instructions may also configure the processor to identify a plurality of points of failure, identify a block associated with a portion of the plurality of points of failure, wherein the block is a region of the non-volatile memory device, determine a total number of points of failure within the block, and mark the block as a bad block in an instance in which the total number of points of failure exceeds of a predetermined threshold value. The point of failure may be a shortage between the first word line and the second word line. The non-volatile memory device may be one of a flash memory device, 3D NOR memory device, 3D ROM memory device, 2D NAND memory device, 3D NAND memory device, 2D NOR memory device, MOS device having cells under regular arrangement, or a device configured for voltage application under regular arrangement.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE SEVERAL VIEWS OF THE DRAWING(S)

Having thus described certain embodiments of the invention in general terms, reference will now be made to the accompanying drawings, which are not necessarily drawn to scale, and wherein:

FIG. 1 is a block diagram of an apparatus for testing word line failure of a non-volatile memory device that may be specially configured in accordance with example embodiments of the present invention;

FIG. 2 is an illustration depicting a two-dimensional (2D) NAND structural diagram in accordance with example embodiments of the present invention;

FIG. 3 is an illustration depicting a point of failure in a 2D NAND structural diagram in accordance with example embodiments of the present invention;

FIG. 4 is an illustration depicting a process for implementing a method for testing word line failure of the non-volatile memory device in accordance with example embodiments of the present invention;

FIG. 5 is an illustration depicting a point of failure in a 2D NAND structural diagram and a 3D NAND structural diagram in accordance with example embodiments of the present invention;

FIG. 6 is an illustration depicting a graphical representation of a chip yield improvement for implementing a method for testing word line failure of the non-volatile memory device in accordance with example embodiments of the present invention;

FIG. 7 is an illustration depicting a numerical representation of a chip yield improvement for implementing a method for testing word line failure of the non-volatile memory device in accordance with example embodiments of the present invention;

FIG. 8 is an illustration depicting a flow diagram of a process for testing word line failure of a non-volatile memory device in accordance with example embodiments of the present invention;

FIG. 9 is an illustration depicting a flow diagram of a process for implementing a method for testing word line failure of a non-volatile memory device in accordance with example embodiments of the present invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

As used in the specification and in the appended claims, the singular forms “a”, “an”, and “the” include plural referents unless the context clearly indicates otherwise. For example, reference to “a NAND structure” includes a plurality of such NAND structures. For example, reference to “a three-dimensional (3D) NAND structure” includes a plurality of two-dimensional (2D) NAND structures.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, a “non-volatile memory device” refers to a semiconductor device which is able to store information even when the supply of electricity is removed. Non-volatile memory includes, without limitation, Mask Read-Only Memory, Programmable Read-Only Memory, Erasable Programmable Read-Only Memory, Electrically Erasable Programmable Read-Only Memory, and Flash Memory, such as NAND and NOR flash memory.

As used herein, a “point of failure” refers to a region of a semiconductor device, more particularly a shortage point between a first word line and a second word line in the non-volatile device, such as 3D NAND flash memory. In one embodiment, a point of failure may be a shortage point due to the manufacturing process. For example, a shortage point may be caused by a deposit of conductive debris between the first word line and the second word line such that current can traverse gaps designed between the first word line and the second word line. For example, a shortage point may be caused by patterning etching process with debris remaining between word lines. In another embodiment, the point of failure may be a shortage point due to the application of high voltage during a programming stage of the non-volatile memory device.

The methods, apparatuses and computer program products of the invention provide for improved chip yield for non-volatile memory devices configured for random access, such as the 3D NAND flash memory by providing improved techniques for addressing points of failure.

The present invention relates to a number of functions, including program (e.g., PGM), erase (e.g., ERS), read (e.g., READ) functions or any other function where a voltage is applied to multiple cells on the same string of the non-volatile memory devices. The present invention may be practiced with various types of devices and/or memory cells including the 3D NAND flash memory, other non-volatile memory devices such as 3D NOR, 3D ROM, 2D NAND, or 2D NOR, MOS cells under regular arrangement, or any other device configured for voltage application under regular arrangement. For the sake of illustration, the example of 2D NAND flash memory is provided herein. It should be appreciated though, that various embodiments of the present invention are also applicable to other types of memories, and indeed embodiments could be applied to any memory device architecture having word lines as described herein.

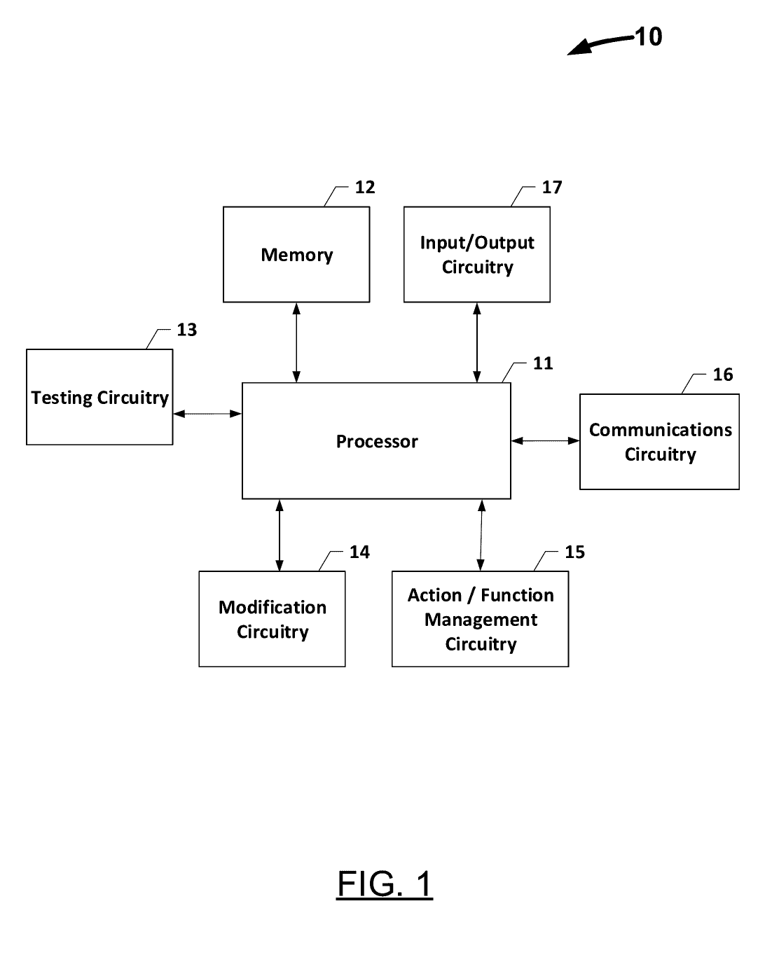

FIG. 1 illustrates a block diagram of an apparatus 10 in accordance with some example embodiments. The apparatus 10 may be any computing device capable of testing word line failure of the non-volatile memory device as described herein. For the purposes of brevity, the apparatus 10 is described as both implementing components and processes for testing word line failure of a non-volatile memory device, though it should be appreciated that such functionality could be split into any number of separate devices. In this regard, the apparatus 10 may be implemented as a standalone or rack-mounted server, a desktop computer, a laptop computer, a personal digital assistant, a tablet computer, a netbook computer, a picture archiving and communication system (PACS) workstation, or the like. Accordingly, it will be appreciated that the apparatus 10 may comprise an apparatus configured to implement and/or otherwise support implementation of various example embodiments described herein.

It should be noted that the components, devices or elements illustrated in and described with respect to FIG. 1 below may not be mandatory and thus some may be omitted in certain embodiments. Additionally, some embodiments may include further or different components, devices or elements beyond those illustrated in and described with respect to FIG. 1.

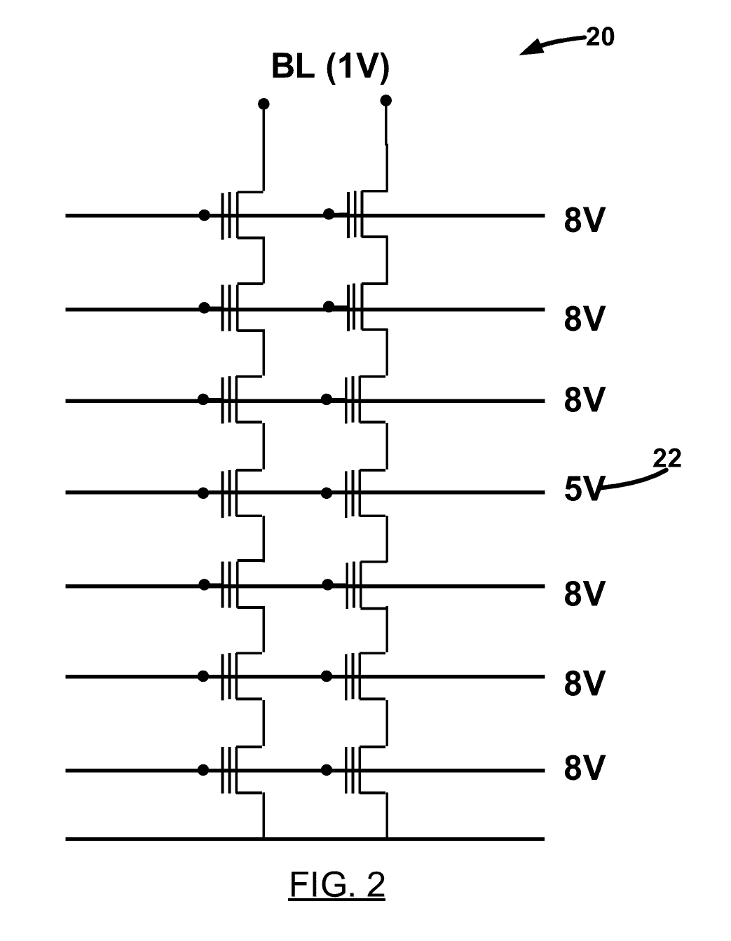

As illustrated in FIG. 1, an apparatus 10 may include a processor 11, a memory 12, a testing circuitry 13, a modification circuitry 14, a management circuitry 15, communications circuitry 16, and input/output circuitry 17. The apparatus 10 may be configured to execute the operations described below with respect to FIGS. 2-9. Although these components 11-17 are described with respect to functional limitations, it should be understood that the particular implementations necessarily include the use of particular hardware. It should also be understood that certain of the apparatus 10 may include similar or common hardware. In various embodiments, two sets of circuitry may both leverage use of the same processor, network interface, storage medium, or the like to perform their associated functions, such that duplicate hardware is not required for each set of circuitry. The use of the term “circuitry” as used herein with respect to components of the apparatus should therefore be understood to include particular hardware configured to perform the functions associated with the particular circuitry as described herein.

The term “circuitry” should be understood broadly to include hardware and, in some embodiments, software for configuring the hardware. For example, in some embodiments, “circuitry” may include processing circuitry, storage media, network interfaces, input/output devices, and the like. In some embodiments, other elements of the apparatus 10 may provide or supplement the functionality of particular circuitry. For example, the processor 11 may provide processing functionality, the memory 12 may provide storage functionality, the communications circuitry 16 may provide network interface functionality, and the like.

In some embodiments, the processor 11 (and/or co-processor or any other processing circuitry assisting or otherwise associated with the processor) may be in communication with the memory 12 via a bus for passing information among components of the apparatus. The memory 12 may be non-transitory and may include, for example, one or more volatile and/or non-volatile memories. In other words, for example, the memory may be an electronic storage device (e.g., a computer readable storage medium). The memory 12 may be configured to store information, data, content, applications, instructions, tables, data structures, or the like, for enabling the apparatus to carry out various functions in accordance with example embodiments of the present invention.

In an example embodiment, the processor 11 may be configured to execute instructions stored in the memory 12 or otherwise accessible to the processor. Alternatively or additionally, the processor may be configured to execute hard-coded functionality As such, whether configured by hardware or software methods, or by a combination thereof, the processor may represent an entity (e.g., physically embodied in circuitry) capable of performing operations according to an embodiment of the present invention while configured accordingly. Alternatively, as another example, when the processor is embodied as an executor of software instructions, the instructions may specifically configure the processor to perform the algorithms and/or operations described herein when the instructions are executed.

In some embodiments, the apparatus 10 may include input/output circuitry 106 that may, in turn, be in communication with processor 11 to provide output to the user and, in some embodiments, to receive an indication of a user input. In various embodiments, the indication can be an identification of the point of failure between the first word line and the second word line. In one embodiment, identification may also represent a selection of various functions to be performed on the non-volatile memory device and/or a selection of various predetermined actions to be performed on the first word line and the second word line. The input/output circuitry 17 may comprise a user interface and may include a display and may comprise a web user interface, a mobile application, a client device, a kiosk, or the like. In some embodiments, the input/output circuitry 17 may also include a keyboard, a mouse, a joystick, a touch screen, touch areas, soft keys, a microphone, a speaker, or other input/output mechanisms. The processor and/or user interface circuitry comprising the processor may be configured to control one or more functions of one or more user interface elements through computer program instructions (e.g., software and/or firmware) stored on a memory accessible to the processor (e.g., memory 12, and/or the like).

The communications circuitry 16 may be any means such as a device or circuitry embodied in either hardware or a combination of hardware and software that is configured to receive and/or transmit data from/to a network and/or any other device, circuitry, or module in communication with the apparatus 10. In this regard, the communications circuitry 16 may include, for example, a network interface for enabling communications with a wired or wireless communication network. For example, the communications circuitry 16 may include one or more network interface cards, antennae, buses, switches, routers, modems, and supporting hardware and/or software, or any other device suitable for enabling communications via a network. Additionally or alternatively, the communication interface may include the circuitry for interacting with the antenna(s) to cause transmission of signals via the antenna(s) or to handle receipt of signals received via the antenna(s).

The testing circuitry 13 includes hardware configured to perform a failure screening of the non-volatile memory device. The testing circuitry 13 may identify the point of failure located between the first word line and the second word line of the non-volatile memory device. The testing circuitry 13 may utilize two-terminal measurement for testing the point of failure. In one embodiment, two adjacent word lines may be pre-charged with different voltages. In the instance of a shortage between the two adjacent word lines, the pre-charged potential will drop accordingly. In some embodiments, the testing circuitry 13 may be included as part of or embodied within modification circuitry, such as described below with respect to the modification circuitry 14. In some embodiments, the testing circuitry 13 and the modification circuitry 14 may be included as part of or embodied within management circuitry, such as described below with respect to the management circuitry 15. It should also be appreciated that, in some embodiments, the testing circuitry 13 may include a separate processor.

The management circuitry 15 includes hardware configured to store, access and edit one or more actions or one or more functions to be performed on the non-volatile memory device. In various embodiment, the management circuitry 15 may control the testing circuitry 13 and the modification circuitry 14 and take appropriate action based on, for example, the results from the testing circuitry 13. For example, the one or more actions may include applying a programing voltage or a bias voltage to both of the first word line and the second word line. Alternatively or additionally, in one embodiment the one or more actions may include one predetermined action of matching the programing voltage or the bias voltage of the second word line to the voltage of the first word line. For example, the bias of the first word line may be varied to judge the different voltage level of memory cell during normal operation, and the second word line may be applied a relatively high voltage to serve as pass-gate, so that the bias of first word line would be decoupled from the second word line. In some embodiments, the one or more functions may include various program function, various erase functions, and various read function of the non-volatile memory device.

The modification circuitry 14 includes hardware configured to perform a marking action on the first word line and the second word line in an instance in which a function is performed on the non-volatile memory device. The modification circuitry 14 may include various applications for retrieving data, uploading data, editing data, viewing data, or the like. For example, the modification circuitry 14 may implement applications such as various customized modification modules for various non-volatile memory device applications. The modification circuitry 14 may utilize the processor 11 to perform these functions, though it should also be appreciated that, in some embodiments, the modification circuitry 14 may include a separate processor, specially configured to implement and execute the application.

The testing circuitry 13 and modification circuitry 14 include hardware configured to execute one or more testing and modification with particular features enabled and/or disabled for the purposes of application testing. In one embodiment, the testing circuitry 13 may interface with the modification circuitry 14 to identify a plurality of points of failure, identify a block associated with a portion of the plurality of points of failure, determine a total number of points of failure within the block, mark the block as a bad block in an instance in which the total number of points of failure exceeds of a predetermined threshold value, and perform the predetermined action on the first word line and the second word line in an instance in which the total number of points of failure does not exceed of the predetermined threshold value.

As will be appreciated, any such computer program instructions and/or other type of code for testing word line failure may be loaded onto a computer, processor or other programmable apparatus's circuitry to produce a machine, such that the computer, processor other programmable circuitry that execute the code on the machine create the means for implementing various functions, including those described herein.

As described above and as will be appreciated based on this disclosure, embodiments of the present invention may be configured as methods, mobile devices, backend network devices, and the like. Accordingly, embodiments may comprise various means including entirely of hardware or any combination of software and hardware. Furthermore, embodiments may take the form of a computer program product on at least one non-transitory computer-readable storage medium having computer-readable program instructions (e.g., computer software) embodied in the storage medium. Any suitable computer-readable storage medium may be utilized including non-transitory hard disks, CD-ROMs, flash memory, optical storage devices, or magnetic storage devices.

Having now described an apparatus configured to implement and/or support implementation of various example embodiments, features of several example embodiments will now be described. It will be appreciated that the following features are non-limiting examples of features provided by some example embodiments. Further, it will be appreciated that embodiments are contemplated within the scope of disclosure that implement various subsets or combinations of the features further described herein. Accordingly, it will be appreciated that some example embodiments may omit one or more of the following features and/or implement variations of one or more of the following features.

FIG. 2 is an illustration depicting a 2D NAND structural diagram 20 in accordance with example embodiments of the present invention. The 2D NAND structural diagram 20 may include a plurality of strings of memory cells comprising a common source line, word line, and bit line according to an embodiment of the invention. In the illustrated embodiment, the string of memory cells comprises one or more word lines 22. Different voltage may be applied to the word line in an instance in which a function is performed on the 2D NAND structural diagram 20. In various embodiments, defects such as the point of failure can occur locally (e.g. between two memory cell) or globally (e.g. between two strings of memory cells).

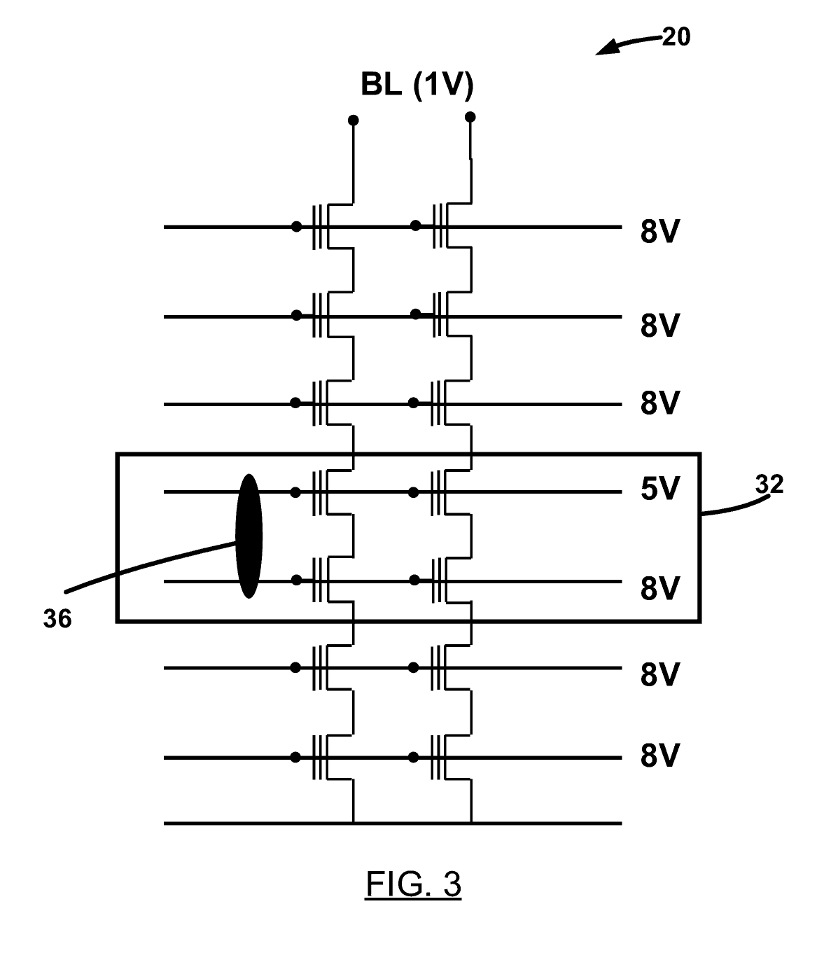

FIG. 3 is an illustration depicting a point of failure 36 in a 2D NAND structural diagram 20 in accordance with example embodiments of the present invention. Due to series connection of the 2D NAND structural diagram 20, in some circumstances, an entire block (e.g. comprising multiple word lines and bit lines) may be marked as a bad block in an instance of the point of failure 36 occurs between two adjacent word lines 32. However, such techniques are inefficient for managing a yield of a manufacturing process, as they require disabling of numerous word and bit lines that do not have a defect. In one embodiment, the point of failure 36 is a local word line defect. The identification of the point of failure 36 may be implemented by, for example, the testing circuitry 13 as described above with respect to FIG. 1. In various embodiments, in the instance the point of failure 36 is occurred between the two adjacent word lines 32, the voltage or potential between the two adjacent word lines 32 is shared. When the two adjacent word lines 32 need to have a different programing voltage applied (e.g. 5V and 8V respectively) in a program or read operation, the operation is likely to fail due to the defect. If the point of failure 36 occurs between two adjacent bit lines, Error Correction Coding (ECC) techniques may be used to address the defect. Alternatively, both global bit line and global word line defects may be modified by redundancy repair (e.g. the global bit line defect is replaced by another working global bit line, and global word line defect is replaced by another working global word line. Bit line defects may affect yield of the non-volatile memory device, however, as a result of these techniques, the impact of bit line defects on the yield of the manufacturing process is relatively low compare to the impact on the yield as a result of word line defects.

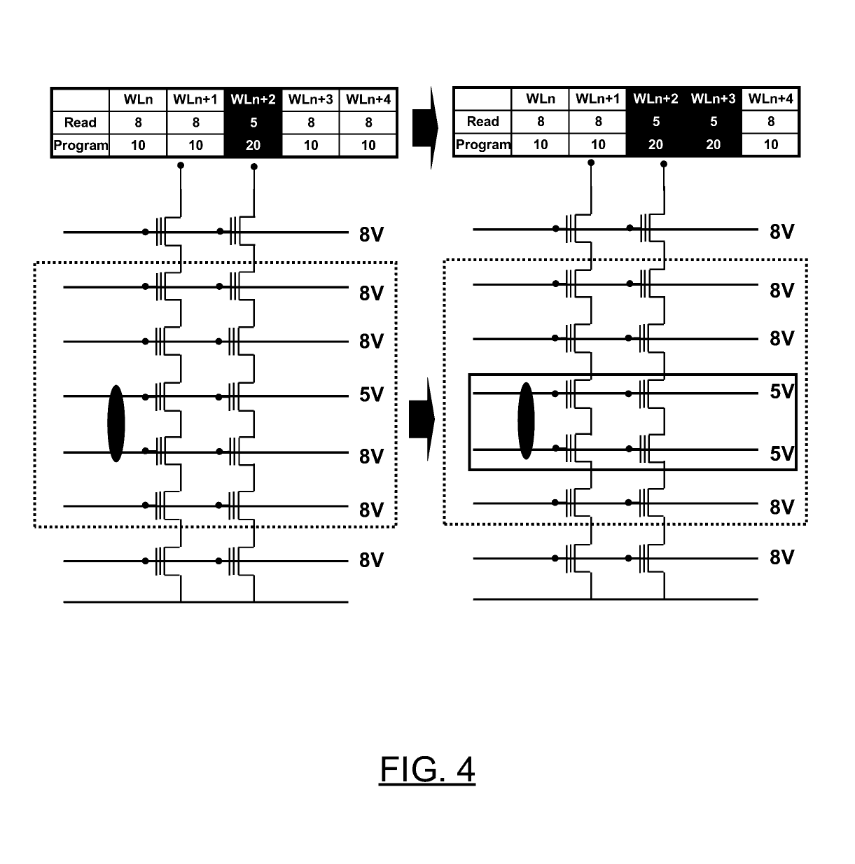

FIG. 4 is an illustration depicting a process for implementing a method for testing for word line failure of a non-volatile memory device in accordance with example embodiments of the present invention. The method may be implemented by, for example, the testing circuitry 13 and the modification circuitry 14 as described above with respect to FIG. 1. In one embodiment, the modification circuitry 14 is configured to mark the two adjacent word lines 32 as a common word line. For example, two adjacent word lines may be marked as a virtual one word line, and same bias voltage is applied from circuit power source. In some embodiments, the screening and marking instructions may be stored on a memory accessible to the processor (e.g., memory 12, and/or the like).

In various embodiments, multiple thresholds may be used to divide word line strings into a plurality of sections or group wherein cells of each section or group are applied a particular programming voltage. For example, a uniform voltage V=5 V is applied to the common word line. In another embodiment, the modification circuitry 14 is further configured to match the read voltage of the second word line to the read voltage of the first word line. For example, a read voltage of 5V may be applied to the second word line instead of 8V. In one embodiment, bias voltages of 0V-5V may be applied to selected word lines during a read mode, and bias voltages of 5V-8V may be applied to pass word lines during the read mode. In another embodiment, bias voltages of 15V-20V may be applied to selected word lines during a programing mode, and bias voltages of 6V-9V may be applied to pass word lines during the programing mode. As the programming function is conducted, different program or read voltages may be selected due to the difference in speed of the cells. In one embodiment, the programming voltage applied to each cell of the string via the corresponding word line may be configured to minimize the variation of the programming voltage for the cells on the string. In one embodiment, the same programming voltages may be applied to each word line comprising the semiconductor device. In another embodiment, the device may be limited to only providing k (k a positive integer) different programming voltages along each word line.

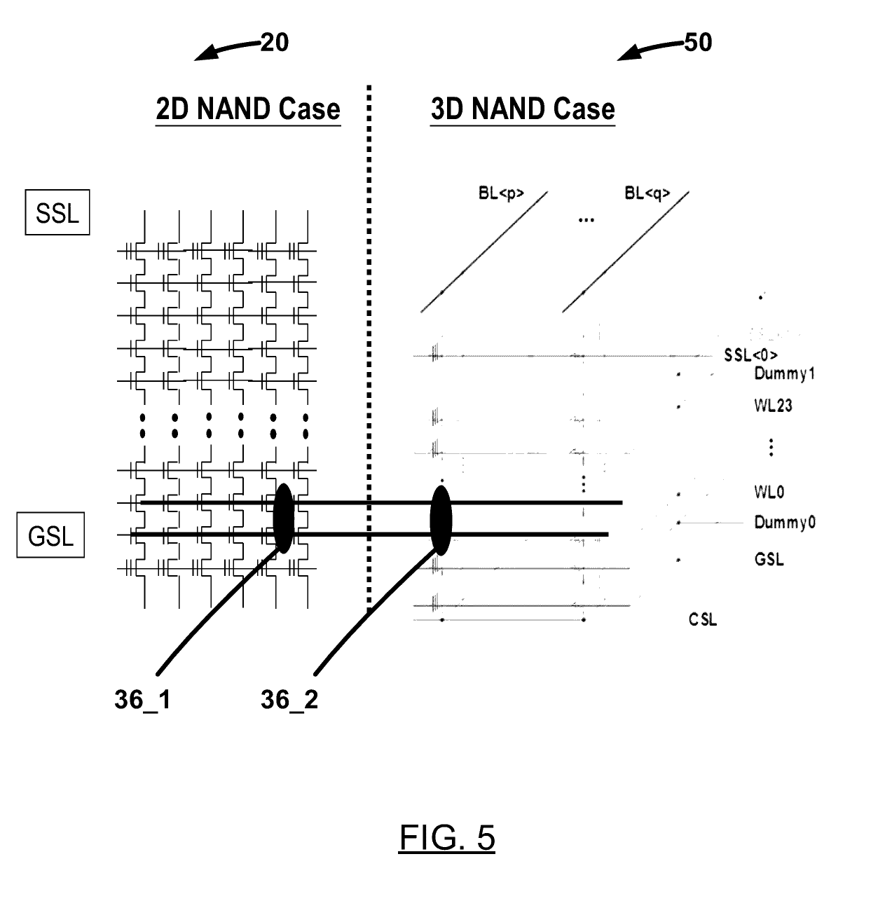

The present invention provides a method, apparatus and computer program product for testing word line failure of a 2D NAND memory device. Same method, apparatus and computer program product may be used for testing word line failure of a 3D NAND memory device. FIG. 5 is an illustration depicting the point of failure 36 in the 2D NAND structural diagram 20 and a 3D NAND structural diagram 50 in accordance with example embodiments of the present invention. In various embodiments, the programing voltage may be applied to each of the two adjacent word lines 32 where the point of failure 36 is shared. In one embodiment, the two adjacent word lines 32 may be located within the same horizontal plane of the 3D NAND structural diagram 50. In another embodiment, the two adjacent word lines 32 may be located within two adjacent horizontal planes of the 3D NAND structural diagram 50 respectively.

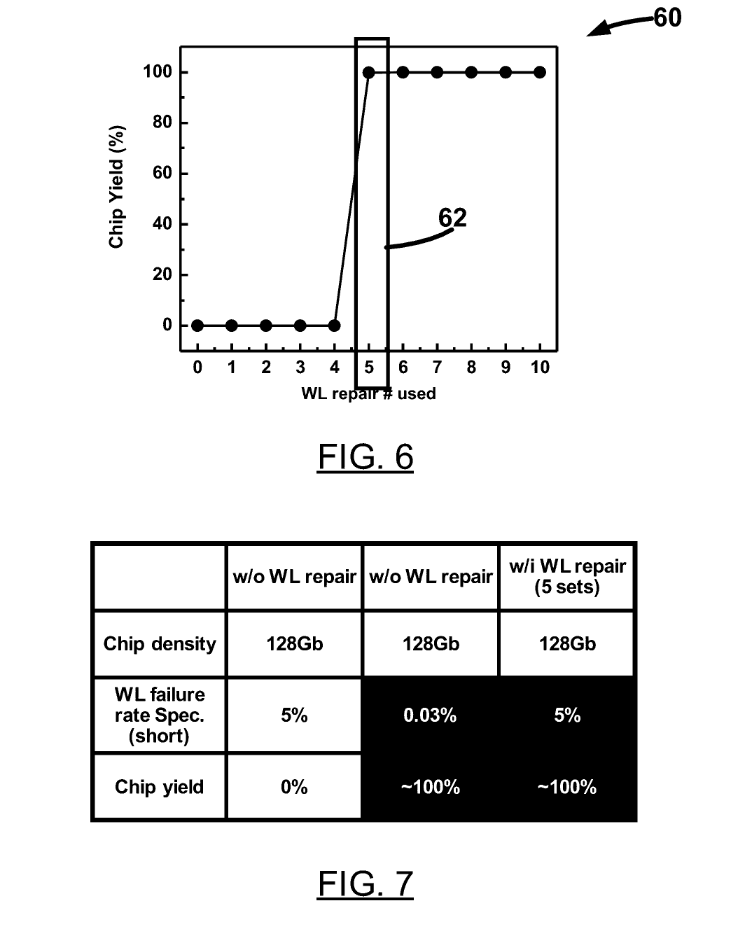

FIG. 6 is an illustration depicting a graphical representation 60 of a chip yield improvement 62 for implementing a method for testing word line failure of a non-volatile memory device in accordance with example embodiments of the present invention. In one embodiment, the percentage of chip yield of the non-volatile memory device is increased from approximately 0% to approximately 100% when more than five word line repair is used. In various embodiments, the chip yield may be associated with a threshold value of allowed maximum repair word line failure spots before the chip design is frozen. For example, the threshold value may be determined by chip overhead or complexities of the chip design. In one example, the threshold value of allowed maximum repair word line failure spots is 5 sets. The threshold value may be applied during the screening stage, where the maximum repair word line failure spots of 5 sets can be marked and applied with the same bias voltage. In one embodiment, when the word line failure rate is 5%, a maximum of 5 sets of word line repair may be used to guarantee the yield.

FIG. 7 is an illustration depicting a numerical representation of a chip yield improvement 62 for implementing a method for testing word line failure of the non-volatile memory device in accordance with example embodiments of the present invention. In one embodiment, chip density, word line failure rate, and number of identified point of failure may be a separate function of the chip yield respectively. In another embodiment, chip density, word line failure rate, and number of identified point of failure may be a numerically combined function of the chip yield. In some embodiments, the distribution of programming voltages may be determined based on chip densities, operational constraints, and/or other considerations. In various embodiments, the chip yield may be improved from 0% to 100% with steady word line failure rate (e.g. 5%) presented in the non-volatile memory device. In one embodiment, the word line failure rate is reduced from 5% to 0.03% by implementing example embodiments of the present invention. In one embodiment, the chip yield may be improved from 0% to 100% with a maximum of 20 sets of word line failure spots presented in the non-volatile memory device.

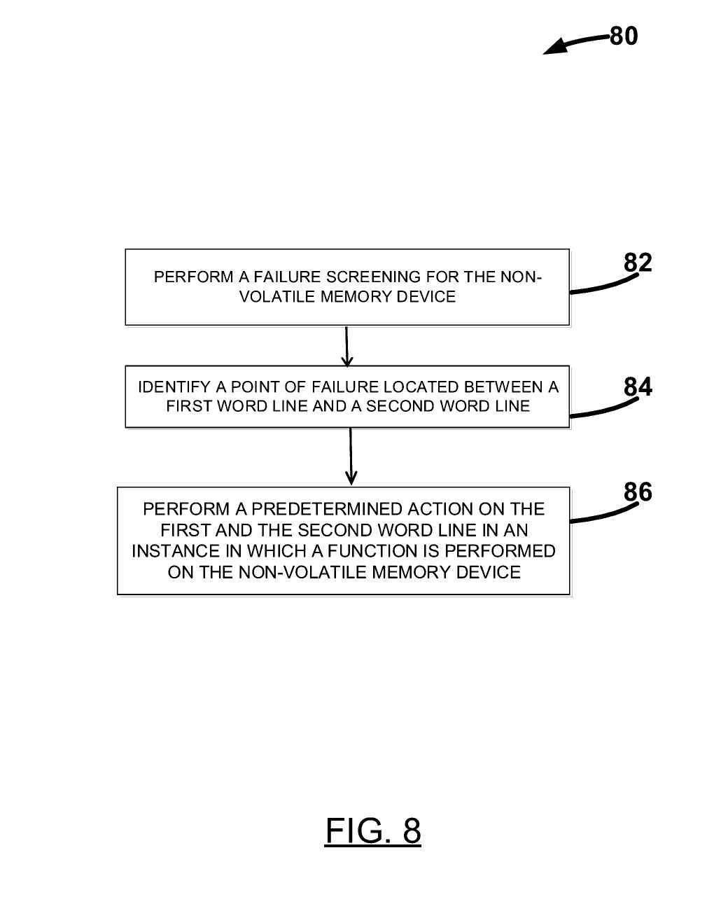

FIG. 8 is an illustration depicting a flow diagram of a process 80 for testing word line failure of a non-volatile memory device in accordance with example embodiments of the present invention. The process 80 may be performed, for example, by an apparatus such as the apparatus 10, through the use of the testing circuitry 13 and the modification circuitry 14 as described above with respect to FIG. 1. The process 80 begins at step 82 by performing a failure screening of the non-volatile memory device. In various embodiments, different portions of the non-volatile memory device may have different screening or testing voltages.

At step 84, a point of failure 36 is identified to be located between a first word line and a second word line. In various embodiment, the point of failure 36 is a shortage between the first word line and the second word line. In one embodiment, the first word line and the second word line is marked as a common word line. In another embodiment, the programming voltage of the second word line is modified to match the programing voltage of the first word line.

At step 86, a marking action is performed on the first word line and the second word line in an instance in which a function is performed on the non-volatile memory device. In various embodiments, the function is one of program, erase, or read. In some embodiments, various actions may be stored, edited, executed through the use of the management circuitry as described above with response to FIG. 1. In one embodiment, the marking action comprising applying same programing voltage to both of the first word line and the second word line respectively.

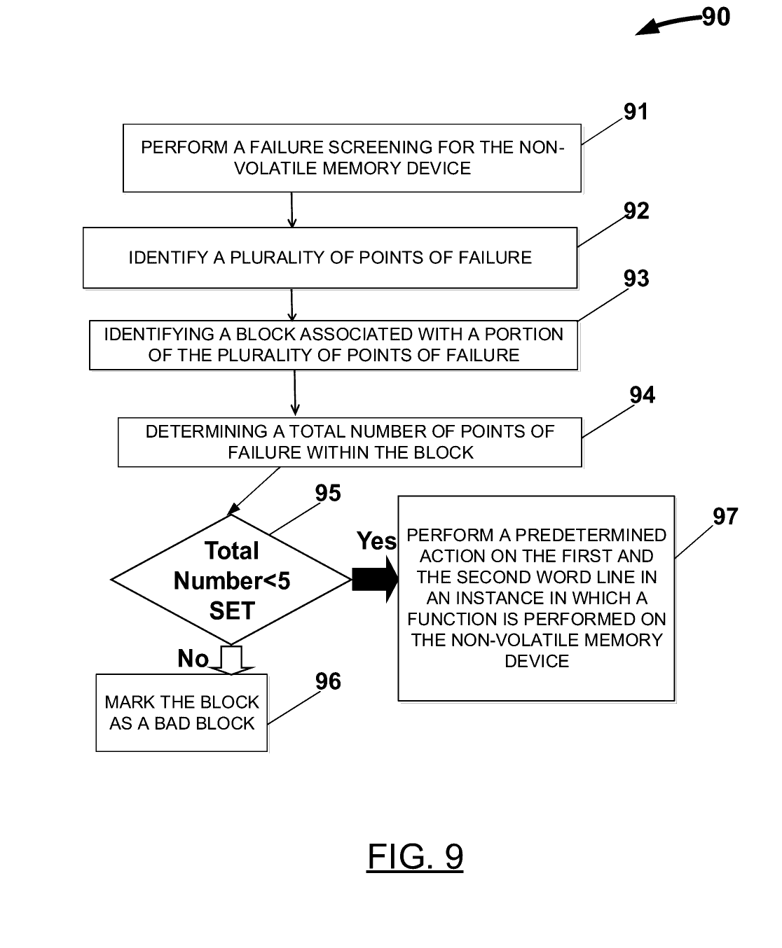

FIG. 9 is an illustration depicting a flow diagram of a process 90 for implementing a method for testing word line failure of a non-volatile memory device in accordance with example embodiments of the present invention. The process 90 may be performed, for example, by an apparatus such as the apparatus 10, through the use of the testing circuitry 13 and the modification circuitry 14 as described above with respect to FIG. 1. The process 90 begins at step 91 by performing a failure screening of the non-volatile memory device. In various embodiments, different portions of the non-volatile memory device may have different screening or testing voltages. At step 92, a plurality of points of failure is identified, wherein each of the plurality of points of failure is located between a first word line and a second word line. In various embodiments, the plurality of points of failure may be a plurality of shortage between sets of the first word line and the second word line.

At step 93, a block is identified associated with a portion of the plurality of points of failure. In various embodiments, the block may be a region of the non-volatile memory device. At step 94, a total number of points of failure is determined within the block. In one embodiment, in the instance in which the total number of points of failure exceeds of a predetermined threshold value, the block is marked as a bad block. In one embodiment, other method such as redundancy word line repair may be used on the block in the instance in which the total number of points of failure exceeds of a predetermined threshold value. For example, a global defect word line is replaced by another working global word line. In one embodiment, in the instance in which the total number of points of failure does not exceed of the predetermined threshold value, the predetermined action is performed on a plurality of first word lines and a plurality of second word lines associated with the plurality of points of failure. In one embodiment, the predetermined threshold value is five.

Any of the processes, methods, or techniques as described herein may be used to accomplish any of these steps of the inventive method.

It will be understood that each element of the flowcharts, and combinations of elements in the flowcharts, may be implemented by various means, such as hardware, firmware, processor, circuitry, and/or other devices associated with execution of software including one or more computer program instructions. For example, one or more of the procedures described above may be embodied by computer program instructions. In this regard, the computer program instructions which embody the procedures described above may be stored by a memory 104 of an apparatus employing an embodiment of the present invention and executed by a processor 102 of the apparatus. As will be appreciated, any such computer program instructions may be loaded onto a computer or other programmable apparatus (e.g., hardware) to produce a machine, such that the resulting computer or other programmable apparatus implements the functions specified in the flowchart blocks. These computer program instructions may also be stored in a computer-readable memory that may direct a computer or other programmable apparatus to function in a particular manner, such that the instructions stored in the computer-readable memory produce an article of manufacture the execution of which implements the function specified in the flowchart blocks. The computer program instructions may also be loaded onto a computer or other programmable apparatus to cause a series of operations to be performed on the computer or other programmable apparatus to produce a computer-implemented process such that the instructions which execute on the computer or other programmable apparatus provide operations for implementing the functions specified in the flowchart blocks.

Accordingly, blocks of the flowchart support combinations of means for performing the specified functions and combinations of operations. It will also be understood that one or more blocks of the flowchart, and combinations of blocks in the flowchart, can be implemented by special purpose hardware-based computer systems which perform the specified functions, or combinations of special purpose hardware and computer instructions.

In some embodiments, certain ones of the operations above may be modified or further amplified. Furthermore, in some embodiments, additional optional operations may be included. Modifications, additions, or amplifications to the operations above may be performed in any order and in any combination.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. A method for testing word line failure of a non-volatile memory device, the method comprising:
performing a failure screening of the non-volatile memory device, wherein the non-volatile memory device comprises one or more word lines;
identifying a point of failure located between a first word line and a second word line; and
marking the first word line and the second word line as a single word line in response to identifying the point of failure between the first word line and the second word line.

2. The method of claim 1, further comprising
applying a bias voltage to both of the first word line and the second word line respectively in an instance in which a function is performed on the non-volatile memory device.

3. The method of claim 2, wherein the function is one of program, erase, or read.

4. The method of claim 1, further comprising:
identifying a plurality of points of failure;
identifying a block associated with a portion of the plurality of points of failure, wherein the block is a region of the non-volatile memory device;
determining a total number of points of failure within the block; and
marking the block as a bad block in an instance in which the total number of points of failure exceeds of a predetermined threshold value.

5. The method of claim 4, wherein the predetermined threshold value is five.

6. The method of claim 1, wherein the point of failure is a shortage between the first word line and the second word line.

7. The method of claim 1, wherein the non-volatile memory device is one of a flash memory device, 3D NOR memory device, 3D ROM memory device, 2D NAND memory device, 3D NAND memory device, 2D NOR memory device, MOS device having cells under regular arrangement, or a device configured for voltage application under regular arrangement.

8. An apparatus for testing word line failure of a non-volatile memory device, comprising:
testing circuitry configured to:
perform a failure screening for a non-volatile memory device, wherein the non-volatile memory device comprises one or more word lines; and
identify a point of failure located between a first word line and a second word line;
modification circuitry configured to:
mark the first word line and the second word line as a single word line in response to identifying the point of failure between the first word line and the second word line.

9. The apparatus of claim 8, wherein the modification circuitry is further configured to apply a bias voltage to both of the first word line and the second word line respectively in an instance in which a function is performed on the non-volatile memory device.

10. The apparatus of claim 9, wherein the function is one of program, erase, or read.

11. The apparatus of claim 8, further configured to:
identify a plurality of points of failure;
identify a block associated with a portion of the plurality of points of failure, wherein the block is a region of the non-volatile memory device;
determine a total number of points of failure within the block; and
mark the block as a bad block in an instance in which the total number of points of failure exceeds of a predetermined threshold value.

12. The apparatus of claim 11, wherein the predetermined threshold value is five.

13. The apparatus of claim 8, wherein the point of failure is a shortage between the first word line and the second word line.

14. The apparatus of claim 8, wherein the non-volatile memory device is one of a flash memory device, 3D NOR memory device, 3D ROM memory device, 2D NAND memory device, 3D NAND memory device, 2D NOR memory device, MOS device having cells under regular arrangement, or a device configured for voltage application under regular arrangement.

15. A non-transitory computer readable storage medium comprising instructions that, when executed by a processor, configure a processor to:
perform a failure screening of the non-volatile memory device, wherein the non-volatile memory device comprises one or more word lines;
identify a point of failure located between a first word line and a second word line; and
mark the first word line and the second word line as a single word line in response to identifying the point of failure between the first word line and the second word line.

16. The non-transitory computer readable storage medium of claim 15, further comprising instructions that configure the processor to:
apply a bias voltage to both of the first word line and the second word line respectively in an instance in which a function is performed on the non-volatile memory device.

17. The non-transitory computer readable storage medium of claim 16, wherein the function is one of program, erase, or read.

18. The non-transitory computer readable storage medium of claim 15, further comprising instructions that configure the processor to:
identify a plurality of points of failure;
identify a block associated with a portion of the plurality of points of failure, wherein the block is a region of the non-volatile memory device;
determine a total number of points of failure within the block; and
mark the block as a bad block in an instance in which the total number of points of failure exceeds of a predetermined threshold value.

19. The non-transitory computer readable storage medium of claim 15, wherein the point of failure is a shortage between the first word line and the second word line.

20. The non-transitory computer readable storage medium of claim 15, wherein the non-volatile memory device is one of a flash memory device, 3D NOR memory device, 3D ROM memory device, 2D NAND memory device, 3D NAND memory device, 2D NOR memory device, MOS device having cells under regular arrangement, or a device configured for voltage application under regular arrangement.
